(19) United States
(12) Patent Application Publication
(10) Pub. No.: US 2026/0150591 A1
(43) Pub. Date: May 28, 2026

(54) SEMICONDUCTOR DEVICE

(71) Applicant: SK hynix Inc., Icheon-si (KR)

(72) Inventor: Young Jae KWON, Icheon-si (KR)

(21) Appl. No.: 19/213,399

(22) Filed: May 20, 2025

(30) Foreign Application Priority Data
Nov. 25, 2024 (KR) 10-2024-0169885

(51) Int. Cl. H10N 70/00; H10B 63/00; H10N 70/20

(52) U.S. Cl. CPC H10N 70/828; H10B 63/00; H10N 70/24

(57) ABSTRACT

A semiconductor device may comprise a first electrode, a second electrode on the first electrode, a resistance change layer between the first electrode and the second electrode, an oxygen reservoir layer disposed between the resistance change layer and the second electrode and including yttria-stabilized zirconia (YSZ), and a porous material layer, contacting the oxygen reservoir layer and including a pore, and positioned on the resistance change layer.

### CROSS-REFERENCE TO RELATED APPLICATION

The present application claims priority under 35 U.S.C. § 119(a) to Korean patent application number 10-2024-0169885 filed on Nov. 25, 2024 in the Korean Intellectual Property Office, which is incorporated herein by reference in its entirety.

### TECHNICAL FIELD

Embodiments of the disclosure relate to a semiconductor device.

### BACKGROUND

As electronic devices are downsized, implemented to have less power consumption and higher performance, and diversified, semiconductor devices that may store information in various electronic devices, such as computers and portable communication devices are being demanded. Recently, semiconductor devices that store data by switching between different resistance states depending on the voltage or current are the subject of research. Such semiconductor devices include resistive random access memory (RRAM), phase-change random access memory (PRAM), ferroelectric random access memory (FRAM), and magnetic random access memory (MRAM).

### SUMMARY

Embodiments of the disclosure may provide a semiconductor device capable of preventing deterioration due to repeated switching operations.

Embodiments of the disclosure may provide a semiconductor device may comprise a first electrode, a second electrode on the first electrode, a resistance change layer between the first electrode and the second electrode, an oxygen reservoir layer disposed between the resistance change layer and the second electrode and including yttria-stabilized zirconia (YSZ), and a porous material layer, contacting the oxygen reservoir layer and including a pore, and disposed on the resistance change layer.

Embodiments of the disclosure may provide a semiconductor device comprising a first conductive line, a second conductive line spaced apart from the first conductive line and crossing the first conductive line, and a pillar structure disposed in an area where the first conductive line and the second conductive line cross each other, wherein the pillar structure includes a first electrode, a second electrode on the first electrode, a resistance change layer between the first electrode and the second electrode, an oxygen reservoir layer disposed between the resistance change layer and the second electrode and including yttria-stabilized zirconia (YSZ), and a porous material layer, contacting the oxygen reservoir layer and including a pore, and disposed on the resistance change layer.

Embodiments of the disclosure may provide a semiconductor device comprising a first electrode, a second electrode on the first electrode, a resistance change layer between the first electrode and the second electrode, an oxygen reservoir layer disposed between the resistance change layer and the second electrode, and a metal-organic framework including a pore, disposed on the resistance change layer and contacting the oxygen reservoir layer, wherein the oxygen reservoir layer fills the pore.

According to embodiments of the disclosure, it is possible to prevent or reduce deterioration due to repeated switching operations.

### BRIEF DESCRIPTION OF THE DRAWINGS

FIG. 1 is a view illustrating an example of a cross-sectional structure of a semiconductor device according to embodiments of the disclosure;

FIG. 2 schematically illustrates a metal-organic framework according to embodiments of the disclosure;

FIG. 3 schematically illustrates an oxygen reservoir layer according to embodiments of the disclosure;

FIG. 4 is an enlarged view of a portion 10 of FIG. 1;

FIG. 5 is a view illustrating an example of a cross-sectional structure of a semiconductor device according to embodiments of the disclosure; and

FIGS. 6 and 7 are views illustrating another example of a semiconductor device according to embodiments of the disclosure.

### DETAIL DESCRIPTION OF THE EXEMPLARY EMBODIMENTS

Hereinafter, various embodiments of the disclosure will be described in detail with reference to accompanying drawings.

In the accompanying drawings, the two directions parallel to the upper surface of the first electrode or the second electrode are defined as a first direction FD and a second direction SD, respectively, and the direction protruding vertically from the upper surface of the first electrode or the second electrode is defined as a third direction VD. The first direction FD and the second direction SD may be substantially perpendicular to each other. The third direction VD is a direction perpendicular to the first direction FD and the second direction SD. In the following specification, ‘vertical’ or ‘vertical direction’ will be used as substantially the same meaning as the third direction VD. The direction indicated by arrow in the drawings and the opposite direction indicate the same direction.

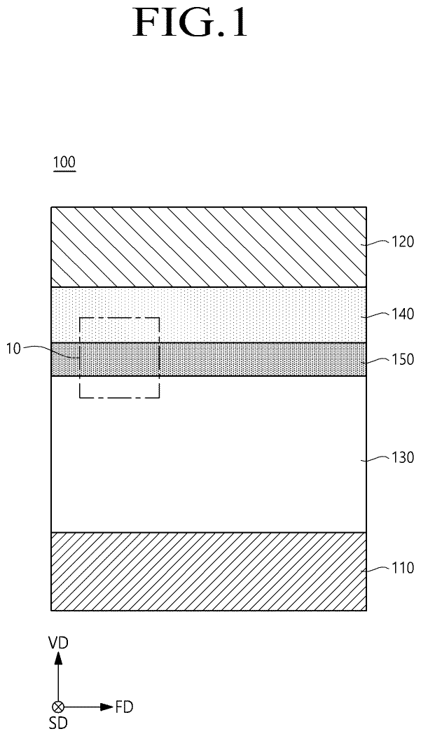

FIG. 1 is a cross-sectional view schematically illustrating a structure of a semiconductor device according to embodiments of the disclosure.

Referring to FIG. 1, a semiconductor device 100 includes a first electrode 110, a second electrode 120, a resistance change layer 130, an oxygen reservoir layer 140, and a porous material layer 150.

The first electrode 110, the second electrode 120, the resistance change layer 130, the oxygen reservoir layer 140, and the porous material layer 150 may be part of components included in the semiconductor device 100. The semiconductor device 100 is not limited to only the above-described components, and the semiconductor device 100 may further include other components in addition to the above-described components.

The first electrode 110 and the second electrode 120 are disposed to be spaced apart from each other in the vertical direction VD. The first electrode 110 and the second electrode 120 may include a conductive material such as metal, metal oxide, metal nitride, or a combination thereof.

The resistance change layer 130 is disposed between the first electrode 110 and the second electrode 120. The resistance change layer 130 is a layer whose resistance changes according to whether a conductive filament is formed. The resistance inside the resistance change layer 130 may vary depending on the length or width of the conductive filament formed in the resistance change layer 130. The resistance change layer 130 may include metal oxide. In an embodiment, the resistance change layer 130 may include hafnium oxide.

The oxygen reservoir layer 140 is disposed between the resistance change layer 130 and the second electrode 120. The oxygen reservoir layer 140 may exchange oxygen ions and oxygen vacancies with the resistance change layer 130. The oxygen reservoir layer 140 may include metal oxide. In an embodiment according to the disclosure, the oxygen reservoir layer 140 may include yttria-stabilized zirconia (YSZ).

The porous material layer 150 is disposed on the resistance change layer 130. The porous material layer 150 may contact the oxygen reservoir layer 140. The porous material layer 150 includes pores. In an embodiment, the porous material layer 150 may include a metal-organic framework. The porous material layer 150 may include a polymer having pores. In an embodiment, the porous material layer 150 may include polymethyl methacrylate (PMMA).

Hereinafter, examples describe the porous material layer 150 as a metal-organic framework, but other embodiments are not limited to use of a metal-organic structure as the porous material layer.

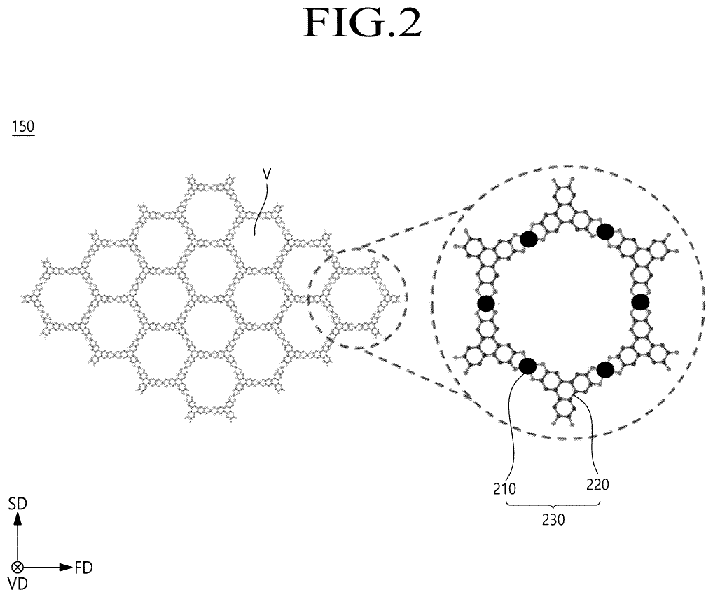

FIG. 2 schematically illustrates a metal-organic framework according to embodiments of the disclosure.

Referring to FIG. 2, the porous material layer 150 may be a metal-organic framework with a frame 230. The frame 230 may include a node 210, which includes a metal, and an organic ligand 220. The metal included in the node 210 may include, for example, manganese (Mn), nickel (Ni), palladium (Pd), platinum (Pt), or the like. The organic ligand 220 may include, for example, oxalic acid, fumaric acid, benzenehexathiol, triphenylenehexathiol, 1-4, benzene dicarboxylic acid, hexaaminobenzene, tetrakis(4-carboxyphenyl)-porphyrinato-cobalt(II), tetrakis(4-carboxyphenyl)-porphyrin), 1,4-dioxido 2,5-benzenedicarboxylate, or the like. As another example, the organic ligand 220 may include H2BDC, H2BDC-Br, H2BDC-OH, H2BDC-NO2, H2BDC-NH2, H4DOT, H2BDC-(Me)2, H2BDC-(CI)2, or the like.

The metal-organic framework may include at least one pore V therein. The pore V may be disposed in an area surrounded by multiple nodes 210 and ligands 220. In an embodiment, the pores V may be arranged in the first direction FD and the second direction SD.

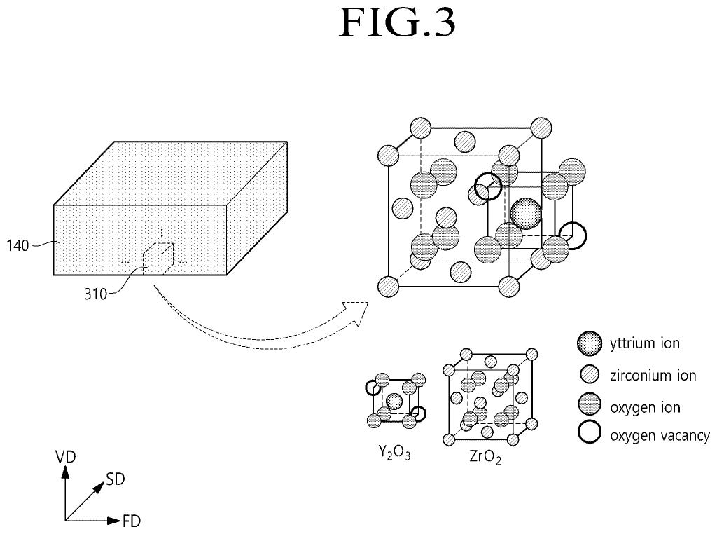

FIG. 3 is schematically illustrates an oxygen reservoir layer according to embodiments of the disclosure.

Referring to FIG. 3, an oxygen reservoir layer 140 may have a lattice structure in which unit cells 310 are regularly arranged. In an embodiment, the oxygen reservoir layer 140 may include YSZ. Hereinafter, an example is described in which the oxygen reservoir layer 140 includes YSZ.

The oxygen reservoir layer 140 includes a plurality of unit cells 310. The unit cells 310 are arranged in a first direction FD, a second direction SD, and a vertical direction VD in the oxygen reservoir layer 140. A unit cell 310 may be formed of one yttrium oxide (Y₂O₃) and one zirconium oxide (ZrO₂). A unit cell 310 may include oxygen vacancies. A plurality of oxygen vacancies may be disposed in the oxygen reservoir layer 140 in which the unit cells 310 are arranged. The oxygen vacancies in the unit cell 310 may be generated by yttrium oxide (Y₂O₃). In an embodiment, the amount of oxygen vacancies included in the oxygen reservoir layer 140 may be adjusted by adjusting the amount of yttrium oxide (Y₂O₃). For example, it is possible to reduce the concentration of oxygen vacancies included in the oxygen reservoir layer 140 by including a lower proportion of yttrium oxide (Y₂O₃) relative to zirconium oxide (ZrO₂) when forming the oxygen reservoir layer 140.

Oxygen ions in the oxygen reservoir layer 140 may move to where the oxygen vacancies are disposed. In an embodiment, the mechanism by which oxygen ions move may include movement by diffusion. The movement of oxygen ions in the oxygen reservoir layer 140 may be determined according to the activation energy of the elements in Table 1 below.

TABLE 1

| | Activation energy (eV) |
|---|---|
| zirconium-zirconium | 0.58 |
| zirconium-yttrium | 1.29 |
| yttrium-yttrium | 1.86 |

Table 1 shows the activation energy required for oxygen ions to move through diffusion in the unit cell 310.

Referring to Table 1, an activation energy of 0.58 eV is required to move (e.g., diffuse) oxygen ions between zirconium atoms in a unit cell 310. Likewise, an activation energy of 1.29 eV is required to move oxygen ions between zirconium and yttrium in a unit cell 310. Further, an activation energy of 1.86 eV is required to move oxygen ions between yttrium atoms.

Referring to FIG. 3, the oxygen vacancies are disposed adjacent to oxygen ions in the unit cell 310 in the first direction FD, the second direction SD, or the third direction VD. The oxygen ions may move in the first direction FD, the second direction SD, or the vertical direction VD toward the position of the closest oxygen vacancy in the unit cell 310.

In order for oxygen ions to move to the closest oxygen vacancy in the first direction FD, energy larger than the energy obtained by adding activation energy (0.58 eV) between zirconium atoms adjacent to each other in the first direction FD and activation energy (1.29 eV) between zirconium and yttrium is required.

Likewise, in order for oxygen ions to move to the closest oxygen vacancy in the second direction SD, energy larger than energy obtained by adding the activation energy (0.58 eV) between zirconium atoms disposed adjacent to each other in the second direction SD and the activation energy (1.29 eV) between zirconium and yttrium is required.

In order for oxygen ions to move to the closest oxygen vacancy in the third direction VD, energy larger than energy obtained by adding the activation energy (0.58 eV) between zirconium atoms adjacent to each other in the third direction VD, the activation energy (1.29 eV) between zirconium and yttrium, and the activation energy (1.86 eV) between yttrium atoms adjacent to each other in the third direction VD is required.

Therefore, the activation energy for the oxygen ions to move to the closest oxygen vacancy in the third direction VD may be larger than the activation energy for the oxygen ions to move to the closest oxygen vacancy in the first direction FD or the second direction SD. In other words, the movement of oxygen ions may occur mainly in the first direction FD or the second direction SD in which the activation energy required for movement is lower, and may occur less frequently in the third direction VD in which the activation energy required for movement is relatively large.

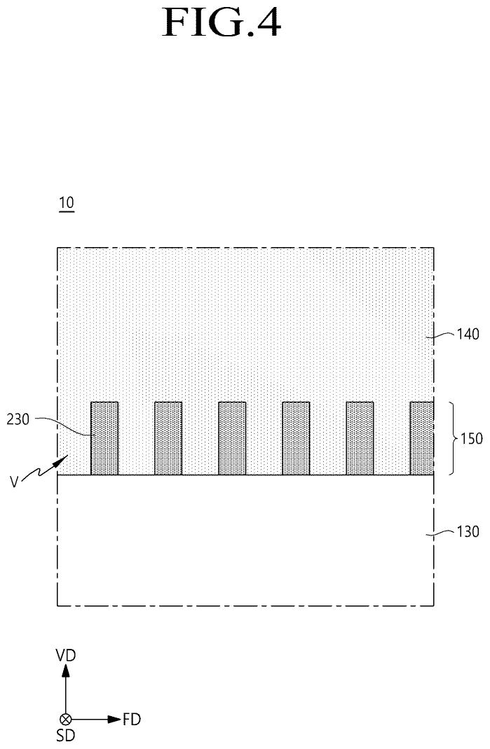

FIG. 4 is an enlarged view of portion 10 of FIG. 1.

Referring to FIG. 4, a porous material layer 150 is disposed on a resistance change layer 130.

An oxygen reservoir layer 140 fills the inside of pores V included in the porous material layer 150. In an embodiment, the oxygen reservoir layer 140 may be formed by an atomic layer deposition (ALD) process. The oxygen reservoir layer 140 contacts the upper surface of the resistance change layer 130 in an area overlapping the pores V. The oxygen reservoir layer 140 may exchange oxygen ions and oxygen vacancies with the resistance change layer 130 through an interfacial reaction with the resistance change layer 130 in the contact area between oxygen reservoir layer 140 and the upper surface of the resistance change layer 130.

In embodiments of the disclosure, when the porous material layer 150 is a metal-organic framework, the oxygen reservoir layer 140 and the upper surface of the resistance change layer 130 do not contact in the areas where frames 230 surround the pores V. Therefore, the oxygen reservoir layer 140 may not exchange oxygen ions and oxygen vacancies with the resistance change layer 130 in the area where the frame 230 is disposed.

Referring to FIGS. 2 and 4, when the porous material layer 150 is disposed at a low density (e.g., when the pore V formed in the porous material layer 150 is large), the area in which the oxygen reservoir layer 140 contacts the resistance change layer 130 may increase. Conversely, when the porous material layer 150 is disposed at a high density (e.g., when the pore V formed in the porous material layer 150 is small), the area in which the oxygen reservoir layer 140 contacts the resistance change layer 130 may be reduced. In other words, depending on the density of the porous material layer 150, the area in which the oxygen reservoir layer 140 and the resistance change layer 130 contact each other may vary.

The size of the pore V may vary depending on the type of the node 210 or the organic ligand 220 included in the metal-organic framework. Alternatively, the size of the pore V may vary depending on the composition of the node 210 or the organic ligand 220.

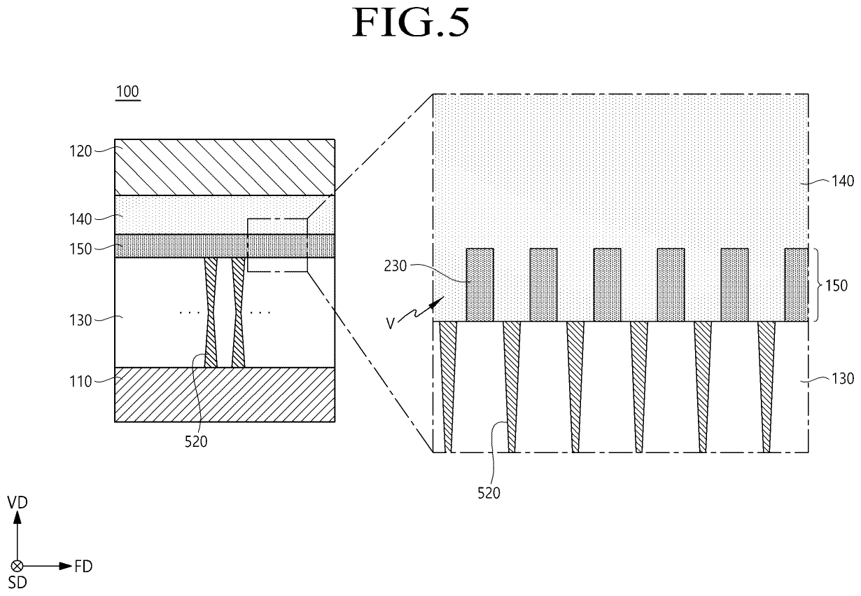

FIG. 5 is a view illustrating an example of a cross-sectional structure of a semiconductor device according to embodiments of the disclosure. Hereinafter, an example in which a semiconductor device is operated is briefly described with reference to FIG. 5.

Referring to FIG. 5, a forming operation is performed on a semiconductor device 100. Specifically, the forming operation may proceed as a process of applying a first voltage larger than or equal to a predetermined threshold voltage between a first electrode 110 and a second electrode 120 of the semiconductor device 100 using a power supply device. The forming operation may be an operation of generating a conductive filament 520 in a resistance change layer 130 immediately after manufacturing the semiconductor device 100.

In an embodiment, the method of applying the first voltage may proceed as a process of applying a bias having a first polarity (e.g., a positive polarity) to the second electrode 120 with the first electrode 110 grounded. By applying the first voltage, oxygen ions included in the resistance change layer 130 may move toward the second electrode 120. Oxygen ions may move inside an oxygen reservoir layer 140.

Further, the oxygen vacancies included in the oxygen reservoir layer 140 may move toward the resistance change layer 130. The oxygen vacancies that move into the resistance change layer 130 may form the conductive filament 520. As the conductive filament 520 electrically connects the first electrode 110 and the second electrode 120, the electrical resistance of the resistance change layer 130 may be reduced.

The conductive filament 520 remains in the resistance change layer 130 even after the first voltage is removed, so a state in which electrical resistance is reduced, i.e., a low resistance state, may be stored as first signal information.

In a state in which the first voltage is applied, the resistance change layer 130 may include one or more conductive filaments 520. In an embodiment, the conductive filaments 520 may be disposed in area overlapping the pores V of the porous material layer 150. Since oxygen ions and oxygen vacancies move to the area where the oxygen reservoir layer 140 contacts the resistance change layer 130, the conductive filaments 520 may be formed in the areas overlapping the pores V.

Thereafter, a first erase operation is performed on the semiconductor device 100. Specifically, the first erase operation may proceed as a process of applying a first erase voltage larger than or equal to a predetermined threshold voltage between the first electrode 110 and the second electrode 120 of the semiconductor device 100 using a power supply device. The first erase operation may be an operation of removing at least a portion (e.g., an intermediate portion) of the conductive filament 520 of FIG. 5 generated in the resistance change layer 130 in the forming operation, which cuts off the electrical connection between the first and second electrodes 110 and 120.

At least a portion (e.g., an intermediate portion) of the conductive filament 520 of FIG. 5 may be removed or degraded by the application of the first erase voltage.

As a result of the first erase operation, the electrical resistance of the resistance change layer 130 may increase. After the first erase voltage is removed, at least a portion of the conductive filament 520 may remain in the resistance change layer 130. Therefore, the state in which the electrical resistance is increased, i.e., a high resistance state, may be stored as second signal information in resistance change layer 130.

The first signal information may be implemented in multiple levels. When the width of the conductive filament changes, the resistance of the resistance change layer 130 may change. Thus, there may be various resistance states in the resistance change layer 130 depending on the width of the conductive filaments. For example, when the width of the conductive filaments increases, the resistance of the resistance change layer may decrease. The first signal information may be divided into various levels according to the width of the conductive filaments.

Alternatively, the second signal information may be implemented to have multiple levels. When a conductive filament is disconnected, the disconnected portions of conductive filament may contact the first electrode 110 and the porous material layer 150, respectively. When the length of the disconnected portions of conductive filament changes the resistance of the resistance change layer 130 may vary. Thus, there may be various resistance states of the resistance change layer 130 according to the lengths of a disconnected conductive filament. For example, when the length of the disconnected conductive filament increases, i.e., if the gap between the disconnected conductive filament segments decreases, the resistance of the resistance change layer may decrease. The second signal information may be divided into various levels according to the length of the disconnected conductive filaments.

Thereafter, a first write operation is performed on the semiconductor device 100. Specifically, the first write operation may proceed as a process of applying a first write voltage larger than or equal to a predetermined threshold voltage between the first electrode 110 and the second electrode 120 of the semiconductor device 100 using a power supply device. The first write operation may be an operation (i.e., a set operation) of reconnecting the disconnected portions of the conductive filament 520, which were disconnected by the first erase operation. Through the set operation, the electrical resistance of the resistance change layer 130 may be turned back to a low resistance state.

In an embodiment, the magnitude of the first write voltage may be smaller than the magnitude of the first voltage. By applying the first write voltage, the disconnected portion of the conductive filament 520 may be recovered. The conductive filament 520 remains in the resistance change layer 130 even after the first write voltage is removed, so the resistance change layer 130 may store a low resistance state, i.e., first signal information.

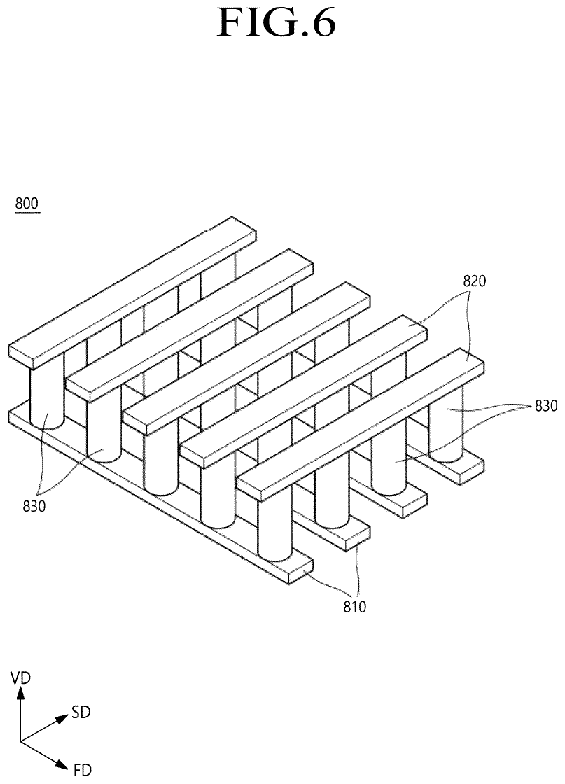

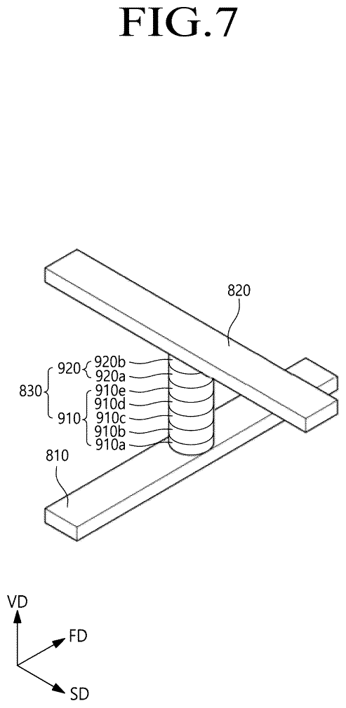

FIGS. 6 and 7 are views illustrating another example of a semiconductor device according to embodiments of the disclosure.

Referring to FIGS. 6 and 7, a semiconductor device 800 includes first and second conductive lines 810 and 820 disposed on different planes, and a pillar structure 830 disposed in an area where the first and second conductive lines 810 and 820 cross each other. The pillar structure 830 may include a memory device 910 and a selection element 920.

Referring to FIG. 6, in the semiconductor device 800, a plurality of first conductive lines 810 are arranged in the first direction FD, and a plurality of second conductive lines 820 are arranged in the second direction SD. A plurality of pillar structures 830, respectively, are disposed in areas where a plurality of first and second conductive lines 810 and 820 cross. The plurality of pillar structures 830 are disposed between the first conductive line 810 and the second conductive line 820. The plurality of pillar structures 830 extend in the vertical direction VD.

Although FIG. 6 illustrates a first direction FD and a second direction SD that are perpendicular to each other, the disclosure is not necessarily limited thereto. In other embodiments, various modifications may result in a condition in which the first direction FD and the second direction SD are not parallel to each other.

Each pillar structure 830 may constitute a memory cell of the semiconductor device 800. The first and second conductive lines 810 and 820 may be signal lines of the semiconductor device 800.

Referring to FIG. 7, the pillar structure 830 may include a memory device 910 disposed on the first conductive line 810. The memory device 910 may include a first electrode 910a, a resistance change layer 910b, a porous material layer 910c, an oxygen reservoir layer 910d, and a second electrode 910e sequentially disposed in the vertical direction VD. The materials and electrical characteristics of the first electrode 910a, the resistance change layer 910b, the porous material layer 910c, the oxygen reservoir layer 910d, and the second electrode 910e of the memory device 910 may be the same as those of the first electrode 110, the resistance change layer 130, the porous material layer 150, the oxygen reservoir layer 140, and the second electrode 120, respectively, included in a semiconductor device 100 of FIG. 1.

Further, the pillar structure 830 may include a selection element 920 disposed on the memory device 910. The selection element 920 may include a selection element layer 920a and a third electrode 920b.

The selection element layer 920a may be a switching layer that performs a threshold switching operation. When the cross-point array device is driven, the selection element layer 920a may perform a function of reducing a leakage current flowing from a neighboring pillar structure. The selection element layer 920a may include, for example, silicon oxide, silicon nitride, metal oxide, metal nitride, or a combination thereof. For example, the selection element layer 920a may include aluminum oxide, zirconium oxide, hafnium oxide, tungsten oxide, titanium oxide, nickel oxide, copper oxide, manganese oxide, tantalum oxide, niobium oxide, or iron oxide.

The third electrode 920b may include a conductive material. The conductive material may include metal, metal nitride, metal oxide, metal silicide, or the like.

The selection element 920 may be, for example, a diode, a tunnel barrier device, or an ovonic threshold switch. As described above, the semiconductor device 800 according to embodiments of the disclosure may be implemented as a cross-point array device including a memory device including a selection element and a resistance change layer.

In another embodiment, the selection element 920 may be omitted and the second electrode 910e of the memory device 910 may be disposed to contact the second conductive line 820.

Although an example in which the semiconductor device 800 is implemented as a cross-point array device is described with reference to FIGS. 6 and 7, the disclosure is not limited thereto. For example, a semiconductor device may be implemented in the form of a 1T1R (1-transistor-1-resistor) in which one memory cell includes one transistor and one memory device. Here, the memory device may be the same as the memory device 910 described above with reference to FIGS. 1 and 7.

Referring back to FIG. 1, a semiconductor device 100 according to embodiments of the disclosure includes an oxygen reservoir layer 140 and a porous material layer 150 including pores. The oxygen reservoir layer 140 may include YSZ. The porous material layer 150 is disposed on the resistance change layer 130. The porous material layer 150 contacts the oxygen reservoir layer 140. The porous material layer 150 may be a metal-organic framework.

In general, the oxygen reservoir layer 140 is formed of a material with lower oxygen vacuum formation energy than the resistance change layer 130. The oxygen reservoir layer 140 may include, for example, tantalum (Ta), titanium (Ti), nickel (Ni), tantalum oxide (TaOx), or the like. When the oxygen reservoir layer 140 includes a material having lower oxygen vacancy formation energy than the resistance change layer 130, oxygen ions may move to the interface between the oxygen reservoir layer 140 and the resistance change layer 130 through an interfacial reaction with the oxygen reservoir layer 140 and the resistance change layer 130, and oxygen vacancies may move to the resistance change layer 130.

However, when the movement of oxygen ions (e.g., in a direction perpendicular to the upper surface of the resistance change layer) occurs freely within the oxygen reservoir layer 140, the oxygen ions may move not only to the interface between the oxygen reservoir layer 140 and the resistance change layer 130, but also to the inside of the oxygen reservoir layer 140. As the set/reset cycles of the semiconductor device are repeated, an additional interfacial reaction between the oxygen reservoir layer 140 and the resistance change layer 130 may occur due to oxygen ions moving into the oxygen reservoir layer 140. Accordingly, more oxygen vacancies may move from the oxygen reservoir layer 140 to the resistance change layer 130. The oxygen vacancies moving into the resistance change layer 130 may form a conductive filament in the resistance change layer 130. As the number of oxygen vacancies moving into the resistance change layer 130 increases, the conductive filament may thicken. When the oxygen vacancies increases above a specific concentration in the resistance change layer 130, the conductive filament may be widen enough to resist breakage or electrical disconnection even when a voltage for a reset operation is applied. In other words, when oxygen ions are move freely (e.g., in a direction perpendicular to the upper surface of the resistance change layer) in the oxygen reservoir layer 140, the concentration of oxygen vacancies moving to the resistance change layer 130 gradually increases as the set/reset cycles are repeated, which may deteriorate the semiconductor device.

On the other hand, when the oxygen reservoir layer 140 includes YSZ, deterioration of the semiconductor device due to repetition of the set/reset cycles of the semiconductor device may be prevented. As described above with reference to FIG. 3, the movement of oxygen ions in a specific direction (e.g., a direction perpendicular to the upper surface of the resistance change layer) is restricted within the YSZ. Therefore, even when the set/reset cycles are repeated, oxygen ions may not move as freely into the oxygen reservoir layer 140 compared to devices without YSZ. Accordingly, it is possible to prevent additional interfacial reactions between the oxygen reservoir layer 140 and the resistance change layer 130, and to prevent continuous increases in the concentration of oxygen vacancies in the resistance change layer 130. In other words, even when the set/reset cycles are repeated, the concentration of oxygen vacancies in the resistance change layer may remain constant, preventing deterioration of the semiconductor device due to repetition of the switching operation.

Further, the concentration of oxygen vacancies included in the oxygen reservoir layer 140 may be adjusted by adjusting the ratio between yttrium oxide (Y₂O₃) and zirconium oxide (ZrO₂) when forming the oxygen reservoir layer 140. Accordingly, the concentration of oxygen vacancies supplied to the resistance change layer 130 may be adjusted.

Further, as described with reference to FIG. 4, the porous material layer 150 according to embodiments of the disclosure may include pores V, and the oxygen reservoir layer 140 may contact the upper surface of the resistance change layer 130 in the area overlapping the pores V.

As described above, the exchange of oxygen ions and oxygen vacancies between the oxygen reservoir layer 140 and the resistance change layer 130 occurs through the interfacial reaction between the oxygen reservoir layer 140 and the resistance change layer 130. As the porous material layer 150 including pores V is disposed on the resistance change layer 130, the area of the interface between the two layers may be selectively adjusted. Accordingly, the concentration of oxygen vacancies supplied to the resistance change layer 130 may be additionally adjusted.

The above-described embodiments are merely examples, and it will be appreciated by one of ordinary skill in the art various changes may be made thereto without departing from the scope of the disclosure. Accordingly, the embodiments set forth herein are provided for illustrative purposes, but not to limit the scope of the disclosure, and should be appreciated that the scope of the disclosure is not limited by the embodiments. The scope of the disclosure should be construed by the following claims, and all technical spirits within equivalents thereof should be interpreted to belong to the scope of the disclosure.

What is claimed is:

1. A semiconductor device, comprising:
a first electrode;
a second electrode on the first electrode;
a resistance change layer between the first electrode and the second electrode;
an oxygen reservoir layer disposed between the resistance change layer and the second electrode and including yttria-stabilized zirconia (YSZ); and
a porous material layer, contacting the oxygen reservoir layer and including a pore, and disposed on the resistance change layer.

2. The semiconductor device of claim 1, wherein the oxygen reservoir layer fills the pore.

3. The semiconductor device of claim 1, wherein the oxygen reservoir layer contacts an upper surface of the resistance change layer.

4. The semiconductor device of claim 1, wherein the oxygen reservoir layer contacts an upper surface of the resistance change layer in an area overlapping the pore.

5. The semiconductor device of claim 1, wherein the resistance change layer further includes a conductive filament whose width changes according to a voltage applied to the second electrode.

6. The semiconductor device of claim 5, wherein the conductive filament overlaps an area where the pore is disposed in a vertical direction.

7. The semiconductor device of claim 1, wherein the porous material layer includes a metal-organic framework.

8. The semiconductor device of claim 1, wherein the porous material layer includes polymethyl methacrylate (PMMA).

9. A semiconductor device, comprising:
a first conductive line;
a second conductive line spaced apart from the first conductive line and crossing the first conductive line; and
a pillar structure disposed in an area where the first conductive line and the second conductive line cross each other, wherein the pillar structure includes:
a first electrode;
a second electrode on the first electrode;
a resistance change layer between the first electrode and the second electrode;
an oxygen reservoir layer disposed between the resistance change layer and the second electrode and including yttria-stabilized zirconia (YSZ); and
a porous material layer, contacting the oxygen reservoir layer and including a pore, and disposed on the resistance change layer.

10. The semiconductor device of claim 9, wherein the oxygen reservoir layer fills the pore.

11. The semiconductor device of claim 9, wherein the oxygen reservoir layer contacts an upper surface of the resistance change layer.

12. The semiconductor device of claim 9, wherein the oxygen reservoir layer contacts an upper surface of the resistance change layer in an area overlapping the pore.

13. The semiconductor device of claim 9, wherein the resistance change layer further includes a conductive filament whose width changes according to a voltage applied to the second electrode.

14. The semiconductor device of claim 13, wherein the conductive filament overlaps an area where the pore is disposed in a vertical direction.

15. The semiconductor device of claim 9, wherein the porous material layer includes a metal-organic framework.

16. The semiconductor device of claim 9, wherein the porous material layer includes polymethyl methacrylate (PMMA).

17. A semiconductor device, comprising:
a first electrode;
a second electrode on the first electrode;
a resistance change layer between the first electrode and the second electrode;
an oxygen reservoir layer disposed between the resistance change layer and the second electrode; and
a metal-organic framework including a pore, disposed on the resistance change layer and contacting the oxygen reservoir layer,
wherein the oxygen reservoir layer fills the pore.

18. The semiconductor device of claim 17, wherein the oxygen reservoir layer includes yttria-stabilized zirconia (YSZ).

19. The semiconductor device of claim 17, wherein the oxygen reservoir layer contacts an upper surface of the resistance change layer.
